(19) United States
(12) Patent Application Publication
(10) Pub. No.: US 2025/0383413 A1
(43) Pub. Date: Dec. 18, 2025

(54) MAGNETIC SENSOR AND MAGNETIC DETECTION METHOD

(71) Applicant: TOHOKU UNIVERSITY, Sendai-shi, Miyagi (JP)

(72) Inventors: Atsushi TSUKAZAKI, Sendai-shi (JP); Kohei FUJIWARA, Sendai-shi (JP); Junichi SHIOGAI, Sendai-shi (JP)

(73) Assignee: TOHOKU UNIVERSITY, Sendai-shi, Miyagi (JP)

(21) Appl. No.: 18/719,165

(22) PCT Filed: Feb. 18, 2022
(86) PCT No.: PCT/JP2022/006778

§ 371 Date: Jun. 12, 2024

(51) Int. Cl. G01R 33/09; G01R 33/02; G01R 33/028; G01R 33/07

(52) U.S. Cl. CPC G01R 33/096; G01R 33/0206; G01R 33/028; G01R 33/07; G01R 33/093

(57) ABSTRACT

A magnetic sensor that can be made smaller, and a magnetic sensor and a magnetic detection method that can reduce power consumption. A current application means applies an alternating current with a frequency ω to a magnetic body. A detection unit finds, when the current is applied by the current application means, a resistance value due to an anomalous Hall effect in the magnetic body from a change in voltage at the frequency ω in a direction perpendicular to a direction in which the alternating current flows and a resistance value due to a unidirectional magnetoresistance effect in the magnetic body from a change in voltage at a frequency 2ω in a direction parallel to the direction in which the alternating current flows. An analysis means can detect a three-dimensional magnetic field based on each resistance values found by the detection unit.

### FIELD OF THE INVENTION

The present invention relates to a magnetic sensor and a magnetic detection method.

### DESCRIPTION OF RELATED ART

A magnetic sensor that detects the direction of a magnetic field by converting the direction into an electrical signal is used for various applications, such as reading a magnetic storage, detecting the position and velocity of a moving body in an electric compass or for automatic piloting, detecting the position or rotation of a drive unit in a machine, and monitoring power consumption by detecting a magnetic field generated by a current. In recent years, as the Internet of Things (IoT) becomes more advanced, there has particularly been increased demand for a three-dimensional magnetic sensor that can detect the direction of a magnetic field. It is also desirable that the three-dimensional magnetic sensor be smaller and consume less power.

In the related art, Hall elements using the Hall effect or magnetoresistance sensors using magnetoresistance are widely used as magnetic sensors. In some configurations, a plurality of elements are arranged three-dimensionally, such as arranging three magnetic sensors in the X, Y, and Z directions in a three-dimensional space, such that a magnetic field is detected three-dimensionally (see, for example, Patent Literature 1 or 2).

The present inventors and others have discovered that an Fe—Sn nanocrystalline thin film, which is a ferromagnetic body, exhibits a large anomalous Hall effect (AHE) comparable to the ordinary Hall effect in semiconductor-based magnetic sensors and can be applied to a Hall sensor (see, for example, Non-patent Literatures 1 to 3). Also, when a current is passed through a ferromagnetic body, the anisotropic magnetoresistance (AMR) effect and the unidirectional magnetoresistance (UMR) effect occur as phenomena in which an external magnetic field alters electrical resistance.

### CITATION LIST

### Patent Literatures

Patent Literature 1: JP 2016-17830 A

Patent Literature 2: JP 2017-26312 A

### Non-patent Literature

Non-patent Literature 1: Y. Satake et al., “Fe—Sn nanocrystalline films for flexible magnetic sensors with high thermal stability”, Sci. Rep., 2019, 9, 3282

Non-patent Literature 2: J. Shiogai, et al., “Low-frequency noise measurements on Fe—Sn Hall sensors”, Appl. Phys. Express, 2019, Vol. 12, Number 12, 123001

Non-patent Literature 3: K. Fujiwara, et al., “Doping-induced enhancement of anomalous Hall coefficient in Fe—Sn nanocrystalline films for highly sensitive Hall sensors”, APL Mater., 2019, Vol. 7, 111103

### SUMMARY OF THE INVENTION

The known magnetic sensors described in Patent Documents 1 and 2 can determine one direction of a magnetic field (e.g., the X, Y, or Z component). However, to detect magnetic field vectors in three directions, a plurality of elements need to be arranged three-dimensionally, which is undesirable because this limits element miniaturization. There is also a problem in that there is a limit to how far power consumption can be reduced because power is consumed based on the number of elements.

The present invention has been made in light of these problems, and an object of the present invention is to provide a magnetic sensor that can be made smaller and a magnetic sensor and a magnetic detection method that can reduce power consumption.

To achieve the above-described object, a magnetic sensor according to the present invention includes a magnetic body; a current application means configured to apply a current to the magnetic body; a detection unit configured to measure, when the current is applied by the current application means, a resistance value due to an anomalous Hall effect in the magnetic body and a resistance value due to a unidirectional magnetoresistance effect in the magnetic body; and an analysis means configured to detect a three-dimensional magnetic field based on the resistance values measured by the detection unit.

Further, in the magnetic sensor according to the present invention, when the current is applied by the current application means, the resistance value due to the anisotropic magnetoresistance effect in the magnetic body is also preferably measured by the detection unit. This configuration is preferable because it enables accurate determination and detection of the three-dimensional magnetic field direction, even in an environment where the magnetic field is not large.

A magnetic detection method according to the present invention is a method of applying an alternating current with a frequency ω to a magnetic body; and detecting a three-dimensional magnetic field based on a resistance value due to an anomalous Hall effect in the magnetic body and a resistance value due to a unidirectional magnetoresistance effect in the magnetic body.

Further, in the magnetic detection method according to the present invention, a resistance value based on the anisotropic magnetoresistance effect in the magnetic body is also preferably used. This configuration is preferable because it enables accurate determination and detection of the three-dimensional magnetic field direction, even in an environment where the magnetic field is not large.

The magnetic detection method according to the present invention can be suitably performed by the magnetic sensor according to the present invention. The magnetic sensor and the magnetic detection method according to the present invention can detect a three-dimensional magnetic field using the anomalous Hall effect in the magnetic body, the anisotropic magnetoresistance (AMR) effect in the magnetic body, and the unidirectional magnetoresistance (UMR) effect in the magnetic body based on the following principle. As illustrated in FIG. 1, when the magnetic body in the form of a thin film is arranged in an X-Y plane, a zenith angle θ_{H}, which is an angle formed by magnetic field vectors relative to the Z-axis perpendicular to the X-Y plane, and an azimuth angle φ_{H} need to be determined independently of one another.

In the present invention, when the anomalous Hall effect occurs when a current is passed through the magnetic body in the X-Y plane, the Hall resistance of the magnetic body indicates output proportional to the Z-axis component of the magnetic field, which makes it possible to uniquely determine the zenith angle θ_{H} of the magnetic field H. Simultaneously, the anisotropic magnetoresistance effect, in which the magnetic resistance fluctuates due to the X-Y plane component of an external magnetic field, has a period of 180 degrees relative to the azimuth of the magnetic field and the unidirectional magnetoresistance effect, which corresponds to the lateral resistance (resistance in the direction of the current) of the magnetic body, has a period of 360 degrees relative to the azimuth of the magnetic field. Thus, by combining the resistance value due to the anisotropic magnetoresistance effect and the resistance value due to the unidirectional magnetoresistance effect, or its positive or negative sign, the azimuth angle φ_{H} can be uniquely determined. Note that, the magnitude of the magnetic field may be found as necessary. For example, the magnitude of the magnetic field H can be found from the magnitude of the anomalous Hall effect or the magnitude of the anisotropic magnetoresistance effect.

Thus, the magnetic sensor and the magnetic detection method according to the present invention can detect a three-dimensional magnetic field using one magnetic body based on resistance values due to the anomalous Hall effect, the anisotropic magnetoresistance effect, and the unidirectional magnetoresistance effect, or the positive or negative sign thereof. Accordingly, compared to magnetic field sensors in the related art which require multiple sensors or multiple elements to be arranged three-dimensionally or over a large space, the magnetic sensor can be made smaller and less expensive. Power consumption of the magnetic sensor can also be reduced due to the small number of elements.

To find the resistance values, in the magnetic sensor according to the present invention, the detection unit preferably finds, when the alternating current with a frequency ω is applied to the magnetic body, the resistance value due to the anomalous Hall effect from a change in voltage at the frequency ω in a direction perpendicular to a direction in which the alternating current flows, the resistance value due to the anisotropic magnetoresistance effect from a change in voltage at the frequency ω in a direction parallel to the direction in which the alternating current flows, and the resistance value due to the unidirectional magnetoresistance effect from a change in voltage at a frequency 2ω in the direction parallel to the direction in which the alternating current flows.

To find the accurate azimuth angle φ_{H} of the magnetic field H, the magnetic sensor and the magnetic detection method according to the present invention preferably acquire a plurality of the resistance values due to the anisotropic magnetoresistance effect at different magnetic field angles.

In this case, for example, the magnetic body preferably includes a first section in which the alternating current flows in a predetermined direction when the alternating current is applied by the current application means, and a second section connected to the first section such that the alternating current flows at the predetermined angle relative to the predetermined direction, and the detection unit preferably uses, as the change in voltage at the frequency ω in the direction parallel to the direction in which the alternating current flows, a change in voltage at the frequency ω in the direction parallel to the direction in which the alternating current flows in the first section and a change in voltage at the frequency ω in the direction parallel to the direction in which the alternating current flows in the second section. With this configuration, since the two resistance values in the first section and the second section are found as the resistance value for the anisotropic magnetoresistance effect with a period of 180 degrees with respect to the azimuth angle of the magnetic field and these resistance values are combined with the resistance value due to the unidirectional magnetoresistance effect, or its positive or negative sign, the azimuth angle φ_{H} can be determined substantially uniquely and accurately. However, since it is difficult to uniquely determine the azimuth angle φ_{H} when the predetermined angle is 90 degrees, 180 degrees, 270 degrees or 360 degrees, the predetermined angle is preferably an angle other than any of these angles.

As a modification of the magnetic sensor and the magnetic detection method according to the present invention, in a case where the unidirectional magnetoresistance effect is sufficiently large and the signal due to the unidirectional magnetoresistance effect is accurate, the azimuth angle φ_{H} can also be determined substantially uniquely and accurately by determining and comparing the resistance values due to the unidirectional magnetoresistance in the first section and the second section. In this case, the magnitude of the magnetic field can also be found by measuring the anisotropic magnetoresistance effect in the first section and the second section.

In the magnetic sensor and the magnetic detection method according to the present invention, the magnetic body that can be used is preferably a material that produces an anomalous Hall effect, an anisotropic magnetoresistance effect, and a unidirectional magnetoresistance effect. More specifically, the magnetic body is preferably a ferromagnetic body of any of Fe—Sn nanocrystal, Co₂MnGa, Co₂MnAl, Fe₃Sn₂ crystal, Fe₃Sn crystal, Co₃Sn₂S₂, (Bi,Sb)₂Te₃ doped with Cr or V, and GaMnAs. Of these, a Fe—Sn nanocrystal, Co₂MnGa, Co₂MnAl, a Fe₃Sn₂ crystal or a Fe₃Sn crystal is preferable because these can be used at room temperature. Further, the thickness of the magnetic body is preferably from 2 nm to 100 nm.

The magnetic sensor and the magnetic detection method according to the present invention preferably include a substrate supporting the magnetic body, and a cap layer for preventing deterioration of the magnetic body, and the magnetic body is preferably made of a thin film and disposed sandwiched between the substrate and the cap layer. In this case, the intensity of the unidirectional magnetoresistance effect increases due to the thickness effect of the magnetic body. Thus, the sensitivity of the magnetic sensor can be increased. Additionally, by increasing the amount of current in the in-plane direction of the magnetic body, the intensity of the anomalous Hall effect, the anisotropic magnetoresistance effect and the unidirectional magnetoresistance effect can be increased and the SN ratio can be increased. In addition, the three-dimensional magnetic field can be found by using a single planar element in which the magnetic body is a thin film, which further reduces the size of the sensor.

Note that, in this case, the substrate is not limited and may be made of SiOₓ (1≤x≤2; silicon oxide), Al₂O₃ (sapphire), MgO, MgAl₂O₄, or another material as long as the magnetic body can be formed on the front surface of the substrate. Additionally, the substrate may be a flexible substrate. The cap layer may be made of any material that can help prevent deterioration of the magnetic body. In particular, the cap layer is preferably made of an insulator that does not let current pass, or a material having good stability in air, such as SiOₓ (1≤x≤2), HfOₓ (1≤x ≤2), AlOₓ (1≤x≤1.5), or SiNₓ (1≤x≤1.33).

According to the present invention, it is possible to provide a magnetic sensor that can be made smaller, and a magnetic sensor and a magnetic detection method that can reduce power consumption.

### BRIEF DESCRIPTION OF THE DRAWINGS

FIG. 1 is a perspective view illustrating the relationship between magnetic field vector, a zenith angle θ_{H}, and an azimuth angle φ_{H} for explaining the principle of detecting a three-dimensional magnetic field H using a magnetic sensor and a magnetic detection method according to the present invention.

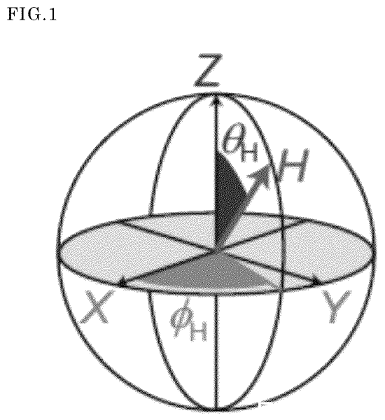

FIG. 2(a) is a schematic perspective view illustrating an overall configuration, and FIG. 2(b) is a perspective view of an element including a magnetic body of the magnetic sensor according to an embodiment of the present invention.

FIG. 3 is a see-through plan view of a cap layer illustrating the magnetic sensor according to the embodiment of the present invention.

FIG. 4 is a graph showing (a) the relationship between the zenith angle θ_{H} of an external magnetic field and a resistance value (R_{H}^{ω}) due to an anomalous Hall effect (AHE), (b) the relationship between the azimuth angle φ_{H} of the external magnetic field and a resistance value (R₁^{ω}) due to an anisotropic magnetoresistance (AMR) effect, and (c) the relationship between the azimuth angle φ_{H} of the external magnetic field and a resistance value (R₁^{2ω}) due to a unidirectional magnetoresistance (UMR) effect, in the magnetic field sensor and the magnetic field detection method according to the embodiment of the present invention.

FIG. 5 is a graph showing the relationship between the zenith angle θ_{H} or the azimuth angle φ_{H} and signs of the resistance value (R_{H}^{ω}) due to the anomalous Hall effect (AHE), the resistance value (R₁^{φ}) due to the anisotropic magnetoresistance (AMR) effect, the resistance value (R₂^{ω}) due to the anisotropic magnetoresistance (AMR) effect, and the resistance value (R₁^{2ω}) due to the unidirectional magnetoresistance (UMR) effect when an angle formed between a first section and a second section of the magnetic body is (a) 45 degrees, (b) 60 degrees, and (c) 105 degrees.

FIG. 6 is an example of a flowchart of a three-dimensional magnetic field detection algorithm in the magnetic field detection method according to the embodiment of the present invention.

FIG. 7 is a graph showing (a) the zenith angle θ_{H} and the azimuth angle φ_{H} of a changed external magnetic field and (b) detected zenith angle θ_{H} and azimuth angle φ_{H} in an experiment of detecting an external magnetic field according to the magnetic sensor and the magnetic detection method according to the embodiment of the present invention.

FIG. 8(a) is a see-through plan view illustrating a cap layer in a modification of an element including the magnetic body of the magnetic sensor according to the embodiment of the present invention, FIG. 8(b) is a plan view illustrating a magnetic field applied to (a) in an experiment of detecting a magnetic field, FIG. 8(c) is an enlarged plan view of a first section (Sample A) of (a), and FIG. 8(d) is an enlarged plan view of a second section (Sample B) of (a).

FIG. 9 is a graph showing (a) the relationship between the azimuth angle φ_{H} of the external magnetic field and the resistance (R_{B}^{ω}) due to the anisotropic magnetoresistance (AMR) effect in the second section (Sample B), (b) the relationship between the azimuth angle φ_{H} of the external magnetic field and the resistance (R_{A}^{ω}) due to the anisotropic magnetoresistance (AMR) effect in the first section (Sample A), and (c) the relationship between the azimuth angle φ_{H} of the external magnetic field and the resistance (R_{A}^{2ω}) due to the unidirectional magnetoresistance (UMR) effect in the first section (Sample A), in an experiment of detecting the magnetic field.

FIG. 10 is a graph showing the ratio of element resistance R₀ to amplitude R^{UMR} of the resistance value due to the unidirectional magnetoresistance (UMR) effect (R^{UMR}/R₀) for a different element structure of the magnetic field sensor according to the embodiment of the present invention.

FIG. 11 is a graph showing the relationship between a thickness t of the magnetic body and the ratio of the element resistance R₀ to the amplitude R^{UMR} of a resistance value (R^{UMR}/R₀) due to the unidirectional magnetoresistance (UMR) effect, and (insert) is a graph showing the relationship between the thickness t of the magnetic body and a reciprocal of the element resistance (1/R₀).

### DETAILED DESCRIPTION OF THE INVENTION

Embodiments of the present invention will be described below with reference to the drawings and examples.

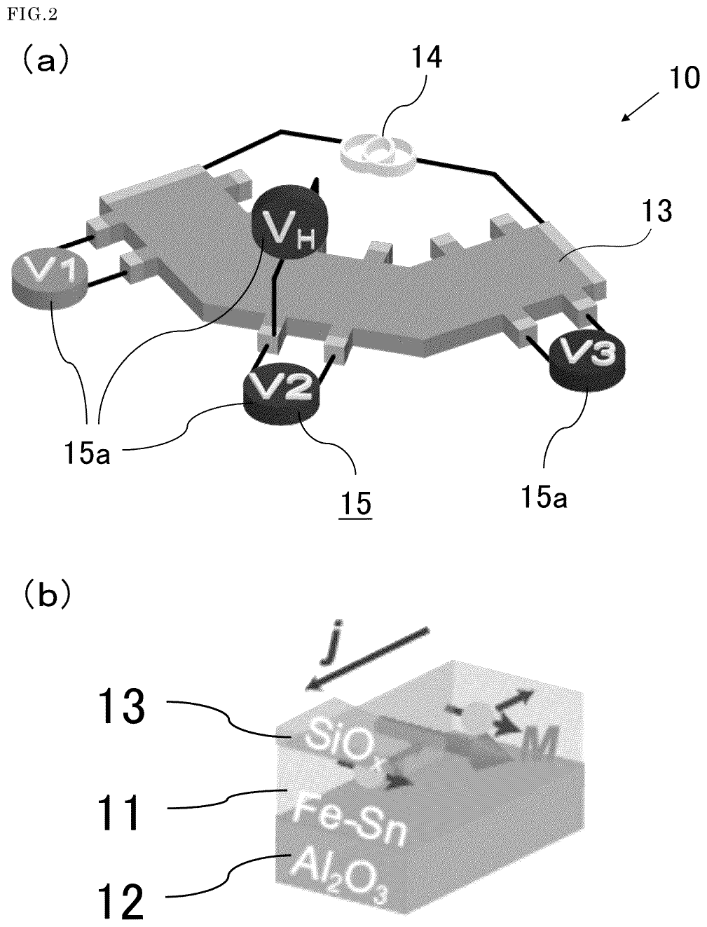

FIGS. 2 to 11 show a magnetic sensor and a magnetic field detection method according to an embodiment of the present invention. As illustrated in FIG. 2, a magnetic sensor 10 includes a magnetic body 11, a substrate 12, a cap layer 13, a current application means 14, a detection unit 15, and an analysis means (not illustrated).

FIG. 2(b) illustrates a cross-section of the stacked structure below the cap layer 13 illustrated in FIG. 2(a). The stacked structure includes the magnetic body 11, the substrate 12, and the cap layer 13. The magnetic body 11 is made of a thin film, is formed on a front surface of the substrate 12 by a thin film formation method, and is supported by the substrate 12. The cap layer 13 is provided covering the front surface of the magnetic body 11 on a side opposite to the substrate 12 to help prevent deterioration of the magnetic body 11 due to oxidation or the like. In other words, the magnetic body 11 is disposed sandwiched between the substrate 12 and the cap layer 13. Note that, for the thin film formation method, a gas-phase process such as sputtering, vapor deposition or CVD, or a liquid-phase process such as plating or a sol-gel process may be used.

In the specific example illustrated in FIG. 2(b), the magnetic body 11 is made of a thin film (thickness: 4 nm) of Fe—Sn nanocrystals. The substrate 12 is made of a sapphire (Al₂O₃) substrate (thickness: 0.33 mm). The cap layer 13 is made of SiOₓ (silicon oxide, thickness: 15 nm). Note that, the magnetic body 11 is not limited to Fe—Sn nanocrystals and may be made of any ferromagnetic material in which the anomalous Hall effect, the anisotropic magnetoresistance effect, and the unidirectional magnetoresistance effect occurs. Specifical examples include Co₂MnGa, Co₂MnAl, Fe₃Sn₂ crystal, Fe₃Sn crystal, Co₃Sn₂S₂, (Bi,Sb)₂Te₃ doped with Cr or V, and GaMnAs. The thickness of the magnetic body 11 is preferably from 2 nm to 100 nm. The substrate 12 is not limited to a sapphire (Al₂O₃) substrate and may be made of SiOₓ (1≤x≤2), MgO, MgAl₂O₄, or another material as long as the magnetic body 11 can be formed on the front surface of the substrate 12. Additionally, the substrate 12 may be made of a flexible material, such as a flexible substrate. The cap layer 13 is not limited to SiOₓ and may be made of HfOₓ (1≤x≤2) or another material as long as that material can help prevent deterioration of the magnetic body 11. In particular, the cap layer 13 is preferably made of an insulator that does not let current pass, or a material having good stability in air.

As illustrated in FIG. 2(a), the magnetic body 11 forming the stacked structure illustrated in FIG. 2(b) is elongated on the surface of the substrate 12 and is connected to the current application means 14 using an electrical connection means across both ends of the magnetic body 11, thereby allowing a current to flow through the magnetic body 11. The magnetic body 11 includes a plurality of linear sections, each with a different direction of extension, from one end to the other. The magnetic body 11 has a structure in which the plurality of linear sections are connected and, in the specific example illustrated in FIG. 2(a), three linear sections are connected. When designating these sections from one end to the other end as a first section, a second section, and a third section, the first section and the third section are connected at different angles relative to the extension direction of the second section. Note that, the number of linear sections of the magnetic body 11 may be two or four or more.

As described above, the current application means 14 is connected to both ends of the magnetic body 11 and is configured to pass a current through the magnetic body 11. In the specific example illustrated in FIG. 2(a), the current application means 14 is configured to pass an alternating current with a frequency ω through the magnetic body 11.

The detection unit 15 includes a voltage measurement means 15a. As illustrated in FIG. 2(a), the voltage measurement means 15a is configured to measure, when the current application means 14 applies a current to the magnetic body 11, voltage in a direction perpendicular to a direction in which the current flows (direction along each linear shape configuring each section of the magnetic body 11) in each section of the magnetic body 11, and voltage in a direction parallel to the direction in which the current flows in each of the plurality of sections of the magnetic body 11. In one specific example illustrated in FIG. 2(a), the voltage measurement means 15a is configured to measure, when the current application means 14 applies an alternating current with the frequency ω to the magnetic body 11, a change in voltage (V_{H}) at the frequency ω in a direction perpendicular to the direction in which the alternating current flows in the second section, a change in voltage (V₁) at the frequency ω in a direction parallel to the direction in which the alternating current flows in the first section, a change in voltage (V₂) at the frequency ω in a direction parallel to the direction in which the alternating current flows in the second section, and a change in voltage (V₃) of a frequency 2ω in a direction parallel to the direction in which the alternating current flows in the third section. Note that, the measurement in the third section in FIG. 2(a) may be made in either the first section or the second section. The change in voltage at the frequency 2ω in the direction parallel to the direction in which the alternating current flows may be measured at any location but is preferably measured at a site in common with the site at which the AMR effect is measured, from the perspective of achieving a smaller element. In this case, the third section is not required.

The analysis means is configured by a computer or the like and is connected to the current application means 14 and the voltage measurement means 15a. The analysis means is configured to find resistance values for each of the changes in voltage based on the current applied by the current application means 14 and each change in voltage measured by the voltage measurement means 15a, and to determine a three-dimensional magnetic field based on the found resistance values.

In one specific example illustrated in FIGS. 2(a) and 2(b), when an external magnetic field acts on the magnetic body 11, of the resistance values found by the analysis means, a resistance value found from the change in voltage (V_{H}) at the frequency ω in the direction perpendicular to the direction in which the alternating current flows is a resistance value due to the anomalous Hall effect in the magnetic body 11, the resistance values found from the changes in voltage (V₁ and V₂) at the frequency ω in the direction parallel to the direction in which the alternating current flows are resistance values due to the anisotropic magnetoresistance effect in the magnetic body 11, and the resistance value found from the change in voltage (V₃) at the frequency 2ω in the direction parallel to the direction in which the alternating current flows is a resistance value due to the unidirectional magnetoresistance effect in the magnetic body 11.

The magnetic detection method according to the embodiment of the present invention can be suitably implemented by the magnetic sensor 10. The magnetic detection method according to the embodiment of the present invention is implemented by applying an alternating current with the frequency ω to the magnetic body 11 by the current application means 14, measuring, by the detection unit 15, the change in voltage at the frequency ω in the direction perpendicular to the direction in which the alternating current flows, the change in voltage at the frequency ω in the direction parallel to the direction in which the alternating current flows, and the change in voltage at the frequency 2ω in the direction parallel to the direction in which the alternating current flows, and detecting a three-dimensional magnetic field based on each of the measured changes in voltage.

In one specific example illustrated in FIG. 2(a), the change in voltage (V_{H}) at the frequency ω in the direction perpendicular to the direction in which the alternating current flows in the second section, the change in voltage (V₁) at the frequency ω in the direction parallel to the direction in which the alternating current flows in the first section, the change in voltage (V₂) at the frequency ω in the direction parallel to the direction in which the alternating current flows in the second section, and the change in voltage (V₃) at the frequency 2ω in the direction parallel to the direction in which the alternating current flows in the third section are measured, and the analysis means finds, for the first section and the second section, the resistance values for each of the changes in voltage and, for the third section, the resistance value or the positive or negative sign of the resistance value, based on the current applied by the current application means 14 and the changes in voltage measured by the voltage measurement means 15a, and then determines the three-dimensional magnetic field based on the found values.

Note that, the detection unit 15 may be, in place of the current measurement means 15a, a resistance measurement means configured to measure resistance values for each of the changes in voltage when the alternating current is applied by the current application means 14. In this case, the analysis means is configured to obtain the three-dimensional magnetic field based on each resistance value measured by the resistance measuring means and, for the third section, the resistance value or the positive or negative sign of the resistance value.

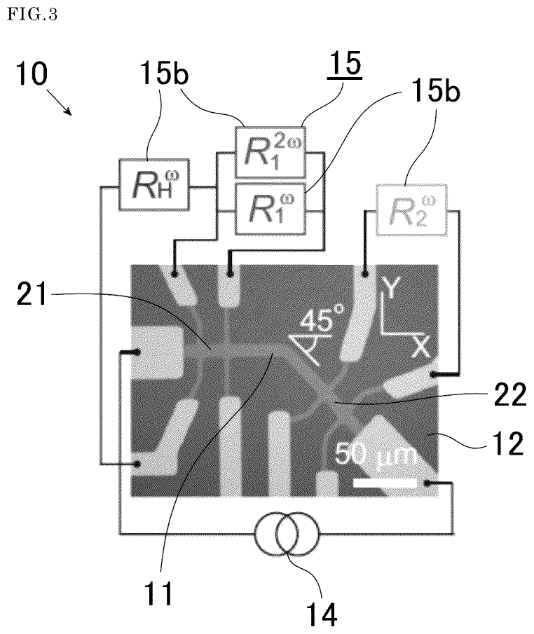

The method of determining the three-dimensional magnetic field will be described in detail with reference to the magnetic sensor 10 illustrated in FIG. 3, which was actually produced and includes two sections. In the magnetic sensor 10 illustrated in FIG. 3, the magnetic body 11 includes two linear sections, where a second section 22 is connected to a first section 21 at one end at a predetermined angle in the extension direction of the first section 21. In the example of FIG. 3, the first section 21 corresponds to a section having the functionality of the second section and the third section in FIG. 2(a), and the second section 22 corresponds to a section having the functionality of the first section in FIG. 2(a). Accordingly, the magnetic sensor 10 illustrated in FIG. 3 is configured to measure, by a resistance measurement means 15b, a resistance value (R_{H}^{ω}) corresponding to the change in voltage at the frequency ω in the direction perpendicular to the direction in which the alternating current flows in the first section 21, a resistance value (R₁^{ω}) corresponding to the change in voltage at the frequency ω in the direction parallel to the direction in which the alternating current flows in the first section 21, a resistance value (R₂^{ω}) corresponding to the change in voltage at the frequency ω in the direction parallel to the direction in which the alternating current flows in the second section 22, and a resistance value (R₁^{2ω}) corresponding to the change in voltage at the frequency 2ω in the direction parallel to the direction in which the alternating current flows in the first section 21. Note that, in the magnetic sensor 10 illustrated in FIG. 3, the angle formed by the first section 21 and the second section 22 is 45 degrees, but this angle is not limited to 45 degrees and may be any angle other than 90 degrees, 180 degrees, 270 degrees, and 360 degrees. Note that, in the circuit illustrated in FIG. 3, the terminals not connected to the current application means 14 and the detection unit 15 may be omitted.

The relationship between the direction of the external magnetic field acting on the magnetic body 11 and the change in resistance values due to the anomalous Hall effect, the anisotropic magnetoresistance effect, and the unidirectional magnetoresistance effect exhibited by the magnetic body 11 is evaluated in advance before the magnetic field is measured. Assuming that the angle between a Z-axis perpendicular to the surface of the magnetic body 11 and a magnetic field vector of the external magnetic field is a zenith angle θ_{H} (0°≤θH≤180°) and the angle of the magnetic field vector of the external magnetic field in a plane parallel to the surface of the magnetic body 11 is an azimuth angle φ_{H} (0°≤φH≤360°), the change in resistance value due to the anomalous Hall effect is R₀cos θ_{H}. Additionally, the change in resistance value due to the anisotropic magnetoresistance effect is R₀sin_{φH}, and has a period of 180 degrees. Additionally, the change in resistance value due to the unidirectional magnetoresistance effect is R₀cos θ_{H}and has a period of 360 degrees. Here, R₀ is the amplitude of each resistance value.

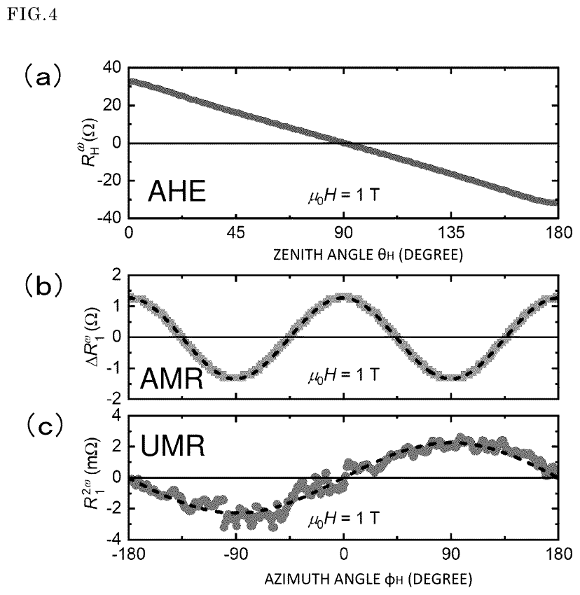

The relationship between the zenith angle θ_{H} of the external magnetic field and the resistance value (R_{H}^{ω}) due to the anomalous Hall effect (AHE) when the alternating current flowing through the magnetic body 11 (in this example, Fe—Sn nanocrystals were used) was I=2^{1/2}I_{ac}cos (ωt), the current density was j=8.75×10⁵ Acm⁻², and the magnetic flux density of the external magnetic field was μ₀H=1 (T) was measured, and the result is shown in FIG. 4(a).

As shown in FIG. 4(a), the relationship between the zenith angle θ_{H} of the external magnetic field and the resistance value (R_{H}^{ω}) due to the anomalous Hall effect (AHE) is a monotonically decreasing function where the resistance value (R_{H}^{ω}) has a maximum value at 0 degrees, is 0Ω at 90 degrees (perpendicular to the external magnetic field), and has a minimum value at 180 degrees, relative to the zenith angle 0°≤θ_{H}≤180°. When an Fe—Sn material is used for the magnetic body 11, due to the tendency of the magnetization to orient within the thin film plane (in-plane magnetic anisotropy), when the magnetic field is 1 T, the change in resistance value due to the anomalous Hall effect does not perfectly follow the magnetic field direction. As a result, the relationship becomes the monotonically decreasing function shown in FIG. 4(a) (note that, in a strong magnetic field of 9 T, for example, the change perfectly follows the function of cos θ_{H}). Note that, for zenith angles of −180°≤θH≤0°, the relationship is a similar monotonically decreasing function where the resistance value (R_{H}^{ω}) has a maximum value at 0° to 0Ω at −90 degrees and a minimum value at −180 degrees. Thus, regardless of whether the change in resistance value due to the anomalous Hall effect perfectly follows the magnetic field, the relationship is a monotonically decreasing function where the resistance value (R_{H}^{ω}) has a maximum value at 0 degrees, is 0Ω at ±90 degrees, and has a minimum value at ±180 degrees. Therefore, the angle in the zenith angular direction can be found by simply measuring either the zenith angle 0°≤θ_{H}≤180° or the zenith angle −180°≤θ_{H}≤0°.

Under the same conditions as in FIG. 4(a), the relationship between the azimuth angle φ_{H} of the external magnetic field and the resistance value (R₁^{ω}) due to the AMR effect and the resistance value (R₁^{2ω}) due to the unidirectional magnetoresistance (UMR) effect in the first section 21 were measured, and the results are shown in FIG. 4(b) and (c), respectively.

As shown in FIG. 4(b), the resistance value (R₁^{ω}) due to the AMR effect has a function with a period of 180 degrees. Note that, while not illustrated, the relationship between the azimuth angle φ_{H} of the external magnetic field and the resistance value (R₂^{ω}) in the second section 22 due to the AMR effect is a relationship in which the azimuth angle φ_{H} is shifted by the angle formed by the first section 21 and the second section 22, with a waveform similar to that in FIG. 4(b). The resistance value (R₁^{ω}) is not accurate based on only the one resistance value (R₁^{ω}) because the change value is small at 90 degrees, 180 degrees, 270 degrees, or 360 degrees. Thus, the accuracy can be improved by using the resistance value (R₂^{ω}) of the second section 22 with the angle formed by the first section 21 and the second section 22 shifted to an angle other than 90 degrees, 180 degrees, 270 degrees, and 360 degrees. This angle is desirably shifted by ±45 degrees or ±135 degrees because values proportional to cos 2θ and sin 2θ can be achieved. However, the angle is not limited thereto and may be an any angle other than 90 degrees, 180 degrees, 270 degrees, and 360 degrees.

As shown in FIG. 4(b), since the resistance value due to the AMR effect has a period of 180 degrees, the polarity (quadrant) of the resistance value cannot be determined, which is a problem. To deal with this, in the related art, the polarity is measured by a different sensor that is separately provided. However, in the present invention, the present inventors devised the idea of using the resistance value (R₁^{2ω}) due to the 360-degree period UMR effect shown in FIG. 4(c) as a result of examining whether polarity determination could be performed without using another sensor.

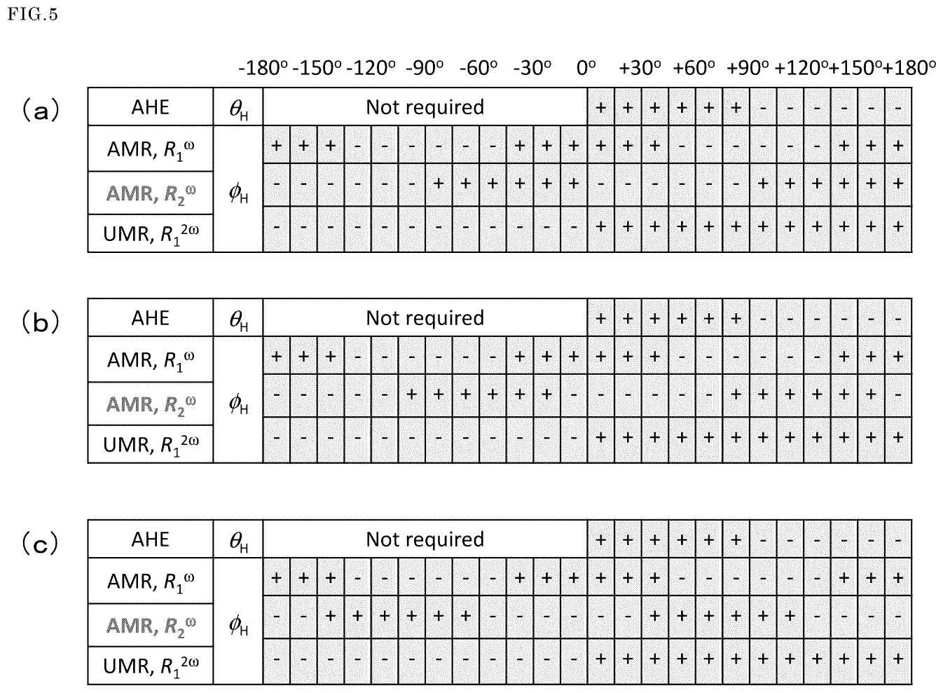

For the relationship shown in FIG. 4, the relationship between the zenith angle θ_{H} or the azimuth angle φ_{H} and the polarity sign of each resistance value when the angle formed by the first section 21 and the second section 22 is 45 degrees, 60 degrees, and 105 degrees is summarized and shown in FIGS. 5(a) to (c), respectively. As shown in FIG. 4(b) and FIGS. 5(a) to (c), the relationship between the azimuth angle φ_{H} and the resistance value due to AMR has a 180-degree period. Therefore, it is difficult to uniquely determine the azimuth angle φ_{H} because the measured resistance value due to AMR in the first section 21 and the second section 22 alone can only narrow down the azimuth angle φ_{H} to two angles. Therefore, as shown in FIGS. 5(a) to (c), finding the resistance value due to the UMR effect makes it possible to determine the polarity and thus uniquely determine the azimuth angle φ_{H}.

As shown in FIGS. 4(b) and 4(c), the resistance value due to UMR is very small compared to the resistance value due to AMR, and the measurement accuracy is somewhat inferior. Thus, only the sign of the resistance value due to UMR may be the focus when combining the resistance value due to UMR with the resistance value due to UMR.

In actual measurement, the zenith angle θ_{H} can be uniquely determined by applying the resistance value R_{H}^{ω} measured by the resistance measurement means 15b of the detection unit 15 to the relationship shown in FIG. 4(a). By applying the measured resistance values R₁^{ω} and R₂^{ω} to FIG. 4(b) and the relationship where the azimuth angle φ_{H} is shifted from FIG. 4(b) by the angle formed by the first section 21 and the second section 22, the azimuth angle φ_{H} can be narrowed down to two angles that are 180 degrees apart. By applying the measured resistance value R₁^{2ω} to the relationship shown in FIG. 4(c) and focusing on its sign, the two azimuth angles φ_{H} that are shifted by 180 degrees can be narrowed down to one, and the azimuth angle φ_{H} can be uniquely obtained.

The magnetic sensor 10 according to the embodiment of the present invention may also measure the magnitude of the magnetic field H, if necessary. The magnitude of the magnetic field can be easily obtained by placing the magnetic sensor in a known magnetic field and measuring values related to the anomalous Hall effect and anisotropic magnetoresistance effect in advance, deriving an equation relating the measured values obtained at that time to the magnetic field, and comparing the values measured in the actual environment with the equation. In the present invention, an AMR element is used. An AMR element is suitable for measuring a magnetic field because there is no magnetic breakdown mode in strong magnetic fields, unlike with giant magneto resistive effect (GMR) and tunnel magneto resistance effect (TMR) elements.

### Three-dimensional Magnetic Field Detection Algorithm of Disclosure

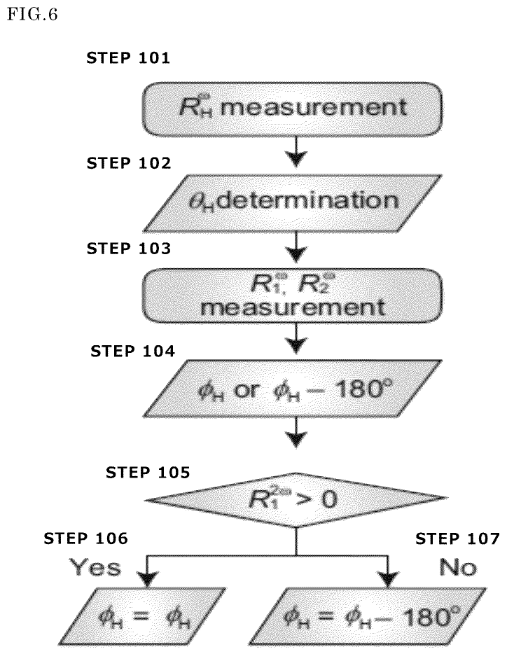

FIG. 6 shows an example of a three-dimensional magnetic field detection algorithm for the magnetic sensor using the resistance value (R_{H}^{ω}) due to the AHE, the resistance value (R₁^{ω}) due to the AMR effect, and the resistance value (R₂^{ω}) and the resistance value (R₁^{2ω}) due to the UMR effect.

### Step 101: Detecting Resistance Value (R_{H}^{ω}) due to AHE

The magnetic sensor 10 according to the embodiment of the present invention was placed in a measurement environment, an alternating current with the frequency ω was applied to the magnetic body 11 by the current application means 14, the change in voltage (V_{H}) at the frequency ω in the direction perpendicular to the direction in which the alternating current flows was measured, and the corresponding resistance value (R_{H}^{ω}) was measured.

### Step 102: Determining Zenith Angle θ_{H}

The obtained resistance value (R_{H}^{ω}) was calculated using the analysis means to find the zenith angle θ_{H} from the relationship between the direction of the external magnetic field acting on the magnetic body 11 and the anomalous Hall effect present in the magnetic body 11, which were determined in advance (where the range of the angular component is 0 degrees≤θ_{H}≤180 degrees).

### Step 103: Detecting Resistance Value (R₁^{ω}) and Resistance Value (R₂^{ω}) due to AMR Effect

The change in voltage (V₁) at the frequency ω in the direction parallel to the direction in which the alternating current flows in the first section and the change in voltage (V₂) at the frequency ω in the direction parallel to the direction in which the alternating current flows in the second section were measured, and the corresponding resistance values (R₁^{ω}) and (R₂^{ω}) were measured.

### Step 104: Determination other than Polarity (Quadrant) of Azimuth Angle φ_{H}

The obtained resistance values (R₁^{ω}) and (R₂^{ω}) were calculated using the analysis means to find the azimuth angle φ_{H} and the azimuth angle φ_{H}−180° from the relationship between the direction of the external magnetic field acting on the magnetic body 11 and the anisotropic magnetoresistance effect present in the magnetic body 11, which were determined in advance (where the range of the angular component is 0°≤φH≤180°).

### Step 105: Detecting Resistance Value (R₁^{2ω}) due to Unidirectional Magnetoresistance (UMR) Effect

The change in voltage (V₃) at the frequency 2ω in the direction parallel to the direction in which the alternating current flows was measured to find the corresponding resistance value (R₁^{2ω}) or the polarity of the resistance value (R₁^{2ω}).

### Steps 106 and 107: Determining Polarity of Azimuth Angle φ_{H}

In a case in which the resistance value or the polarity of the resistance value found in Step 105 is 0Ω or more or positive, φ_{H} among the azimuth angle θ_{H} and the azimuth angle φ_{H}−180° found in Step 104 is determined as the azimuth angle φ_{H} (Step 106). On the other hand, in a case in which the resistance value or the polarity of the resistance value found in Step 105 is less than 0Ω or negative, φ_{H}−180° among the azimuth angle φ_{H} and the azimuth angle φ_{H}−180° found in Step 104 is determined as the azimuth angle φ_{H} (Step 107).

The algorithm of the above steps is used to determine the three-dimensional magnetic field. Note that, the flowchart in FIG. 6 is merely an example, and the order and other details can be changed as needed. For example, since the zenith angle θ_{H} and the azimuth angle φ_{H} are determined independently, the azimuth angle φ_{H} may be determined first, then the zenith angle θ_{H} may be determined, or the azimuth angle φ_{H} and the zenith angle θ_{H} may be calculated and determined simultaneously.

As described above, in the magnetic sensor 10 and the magnetic detection method according to the embodiment of the present invention, the magnetic body 11 can be solely used to detect the three-dimensional magnetic field based on the resistance values due to the anomalous Hall effect, the anisotropic magnetoresistance (AMR) effect and the unidirectional magnetoresistance (UMR) effect present in the magnetic body 11. Accordingly, since there is no need to use a sensor other than that in the configuration of the present invention, the magnetic field sensor can be made smaller and less expensive than conventional magnetic field sensors, which have multiple elements arranged in a three-dimensional configuration. In addition, the three-dimensional magnetic field can be found by using a single planar element in which the magnetic body 11 is a thin film, which further reduces the size of the sensor. Additionally, power consumption can be reduced because the number of elements is small.

In the magnetic sensor 10 and the magnetic detection method according to the embodiment of the present invention, the intensity of the unidirectional magnetoresistance effect increases due to the thin-film effect of the magnetic body 11 made of a thin film. Thus, the sensitivity of the magnetic sensor 10 can be increased. Additionally, by increasing the amount of current in the in-plane direction of the magnetic body 11, the intensity of the anomalous Hall effect, the anisotropic magnetoresistance effect and the unidirectional magnetoresistance effect can be increased and the SN ratio can be increased.

In the magnetic sensor 10 and the magnetic detection method according to the embodiment of the present invention, the sensor can be made smaller and power consumption can be reduced, which is useful for aggregating elements including the magnetic sensor 10 and can contribute to progression of a smart society through IoT, for example.

### Modifications

The above description relates to the magnetic sensor 10 that can detect a three-dimensional magnetic field using the anomalous Hall effect (AHE), the anisotropic magnetoresistance (AMR) effect and the unidirectional magnetoresistance (UMR) effect. However, since the unidirectional magnetoresistance (UMR) effect has a period of 360 degrees, depending on conditions, it is possible for the magnetic sensor 10 to use only the anomalous Hall effect (AHE) and the unidirectional magnetoresistance (UMR) effect to detect the three-dimensional magnetic field, thereby further simplifying the magnetic sensor.

In a case where the UMR effect is sufficiently large and the signal is accurate, a configuration may be adopted where the change in voltage at the frequency 2ω in the direction parallel to the direction in which the alternating current flows in the first section 21, and the change in voltage at the frequency 2ω in the direction parallel to the direction in which the alternating current flows in the second section 22 are measured, as illustrated in FIG. 3. More specifically, FIG. 3 illustrates a configuration in which the resistance value (R₁^{2ω}) corresponding to the change in voltage at the frequency 2ω in the direction parallel to the direction in which the alternating current flows in the first section 21 and the resistance value (R₂^{2ω}) corresponding to the change in voltage at the frequency 2ω in the direction parallel to the direction in which the alternating current flows in the second section 22 are measured.

In this case, it is not necessary to measure the change in voltage (V₁) at the frequency ω in the direction parallel to the direction in which the alternating current flows (corresponding resistance value (R₁^{ω})) in the first section 21 and the change in voltage (V₂) at the frequency ω in the direction parallel to the direction in which the alternating current flows (corresponding resistance value (R₂^{2ω})) in the second section, which can simplify the element structure.

In this modification, the three-dimensional magnetic field can be detected based on the resistance values due to the anomalous Hall effect and the UMR effect, which also allows for further element miniaturization. If the magnitude of the magnetic field also needs to be found, the magnitude can be found from the anomalous Hall effect as described above. In some cases, the magnitude of the magnetic field can also be found by detecting the resistance value due to the anisotropic magnetoresistance effect by the detection unit 15.

### EXAMPLE 1

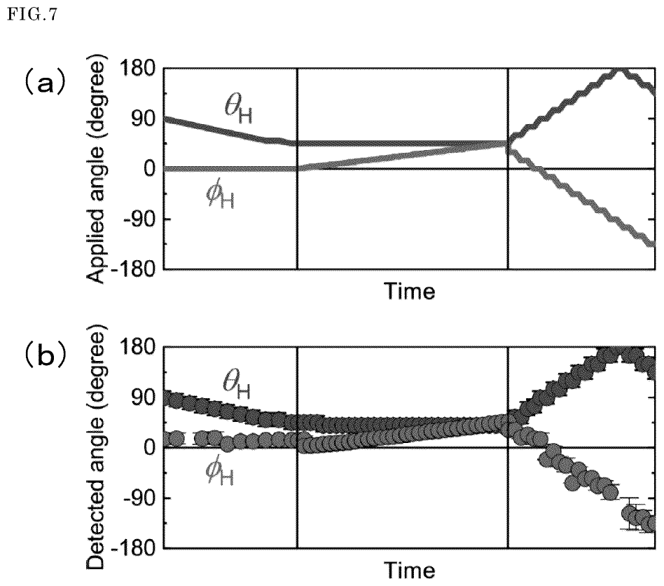

An experiment was conducted using the magnetic sensor 10 shown in FIG. 3 to detect the magnetic field while varying the angles of the external magnetic field (zenith angle θ_{H} and azimuth angle φ_{H}). In the experiment, the current density of the alternating current flowing through the magnetic body 11 was set to j=5×10⁵ Acm⁻² and the flux density of the external magnetic field was set to μ₀H=1 (T). The zenith angle θ_{H} and the azimuth angle φ_{H} of the varied external magnetic field are shown in FIG. 7(a), and the zenith angle θ_{H} and azimuth angle φ_{H} detected by the magnetic sensor 10 are shown in FIG. 7(b).

In FIG. 7(a), the magnetic sensor 10 was arranged at a position where the initial zenith angle θ_{H}=90 degrees and the azimuth angle φ_{H}=0 degrees. First, the external magnetic field was moved such that the azimuth angle remained the same but the direction of the zenith angle was shifted (Process 1). Next, the direction of the azimuth angle was moved so that it was shifted from its initial value, without moving the zenith angle from this initial state (Process 2). Lastly, with the zenith angle and azimuth angle shifted from their initial positions, both angles were moved to shift the angles (Process 3).

FIG. 7(b) shows the three-dimensional angles detected by the magnetic sensor 10. Comparing FIGS. 7(a) and 7(b), it can be seen that the magnetic field follows the changes in angles and the magnetic sensor 10 accurately finds the three-dimensional angles. Thus, it was confirmed that the magnetic sensor 10 accurately detected the angles of the magnetic field.

### EXAMPLE 2

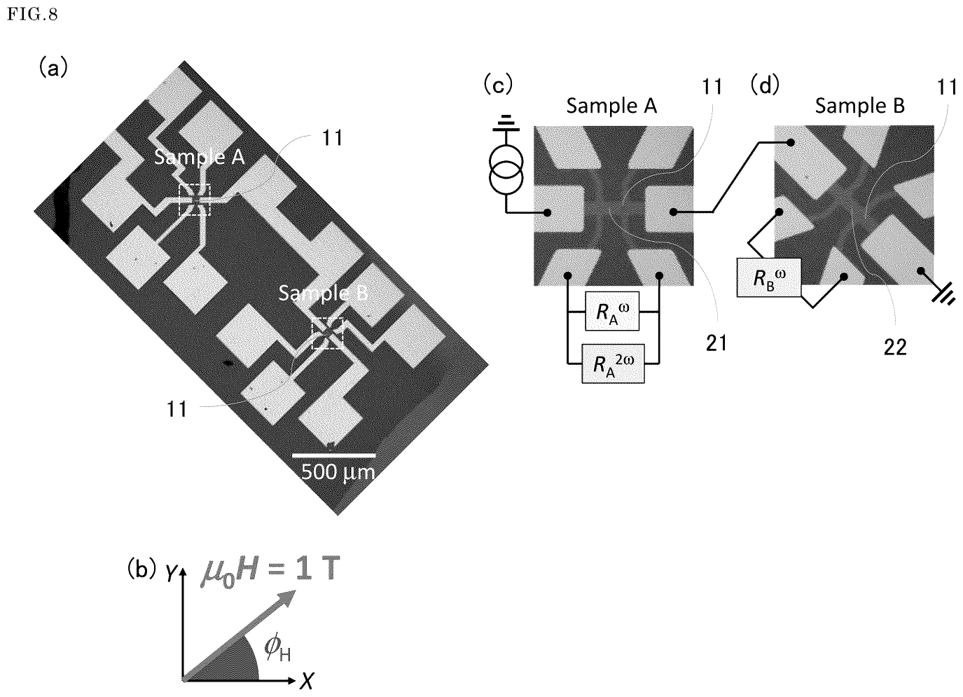

As shown in FIGS. 8(a), 8(c), and 8(d), a magnetic sensor 10 in which the first section 21 (Sample A in the figure) and the second section 22 (Sample B in the figure) of the magnetic body 11 were arranged separated from each other on one substrate 12 and the first section 21 and the second section 22 are electrically connected was produced, and an experiment was conducted to detect the magnetic field. The angle formed by the direction of extension of the first section 21 and the direction of extension of the second section 22 was 45 degrees. In the experiment, as shown in FIG. 8(b), a magnetic field (zenith angle θ_{H}=90 degrees) with a magnetic flux density _{μ0}H=1 (T) and the azimuth angle φ_{H} was applied along the front surface (X-Y plane) of the magnetic body 11. The current density of the alternating current flowing through the magnetic body 11 was set to j=5×10⁵ Acm⁻². The resistance value (R_{A}^{ω}) due to the anisotropic magnetoresistance (AMR) effect and the resistance value (R_{A}^{2ω}) due to the unidirectional magnetoresistance (UMR) effect in the first section 21 (Sample A) were measured and the resistance value (R_{B}^{ω}) due to the anisotropic magnetoresistance (AMR) effect in the second section 22 (Sample B) was measured.

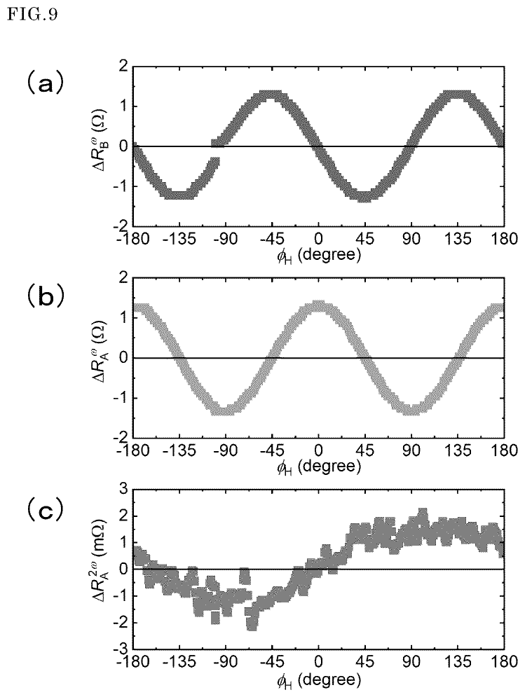

The measurement results of each resistance value are shown in FIGS. 9(a) to (c). As shown in FIGS. 9(a) and 9(b), it was confirmed that the phase of the waveform of the resistance value R_{A}^{ω} and the phase of the waveform of the resistance value R_{B}^{ω} were measured with the same 45-degree shift as the angle formed by the first section 21 and the second section 22. This indicates that the magnetic field can be measured even when the first section 21 and the second section 22 are placed far apart, as long as the magnetic field to be detected does not change. In FIG. 8(a), the first section 21 and the second section 22 are arranged on a single substrate 12. However, provided that the sections are electrically connected, the sections need not be arranged on a single substrate 12 and may be arranged on different substrates 12. In this case, if the sections are formed on a single substrate, the magnetic field may be different in each section due to the distance between the sections. However, if the sections are stacked, the same magnetic field is more likely to be applied to both the sections, which is expected to improve accuracy. This also allows each section to be arranged stacked not only on the left and right, but also on the top and bottom, for example, to reduce the size and increase the degree of freedom in arranging the magnetic sensor on the device.

### EXAMPLE 3

Experiments were conducted to detect the magnetic field after changing the materials of the substrate 12 and the cap layer 13 of the magnetic sensor 10 shown in FIG. 3. In these experiments, the element structure of the magnetic sensor 10, which consists of the cap layer 13 (thickness: 15 nm)/the magnetic body 11 (thickness: 4 nm)/the substrate 12 (thickness: 0.33 mm for Al₂O₃, thickness: 0.50 mm for other materials), was composed of HfOₓ/Fe—Sn/Al₂O₃, SiOₓ/Fe—Sn/Al₂O₃, SiOₓ/Fe—Sn/MgO, SiOₓ/Fe—Sn/MgAl₂O₄, and SiOₓ/Fe—Sn/SiOₓ/Al₂O₃ with SiOₓ (thickness: 15 nm) inserted as a lower layer between the magnetic body 11 (thickness: 4 nm) and the substrate 12 (thickness: 0.33 mm) (in the drawing, SiOₓ/Fe—Sn/SiOₓ is shown). The current density of the alternating current flowing through the magnetic body 11 was set to j=5×10⁵ Acm⁻², and the flux density of the external magnetic field was set to _{μ0}H=1 (T). In these experiments, the ratio of amplitude R^{UMR} of the measured resistance value due to the unidirectional magnetoresistance (UMR) effect to element resistance R₀ (R^{UMR}/R₀) was found.

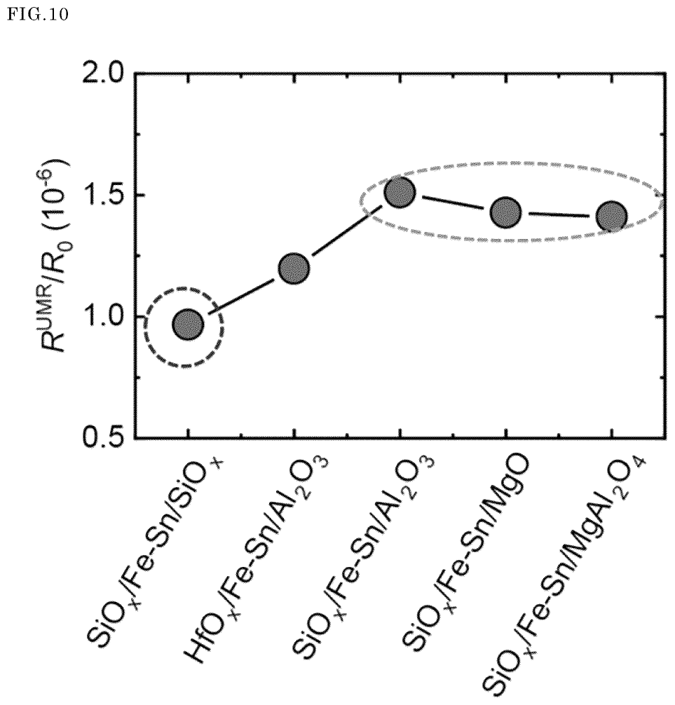

The values of R^{UMR}/R₀ for each element structure are shown in FIG. 10. As shown in FIG. 10, the values of R^{UMR}/R₀ for the three element structures of SiOₓ/Fe—Sn/Al₂O₃, SiOₓ/Fe—Sn/MgO, and SiOₓ/Fe—Sn/MgAl₂O₄ are larger than those for the other two element structures, and the unidirectional magnetoresistance effect is relatively large. This indicates that the element structure can increase the unidirectional magnetoresistance effect and improve the accuracy of magnetic field measurement.

### EXAMPLE 4

Experiments were conducted on the magnetic sensor 10 shown in FIG. 3 to detect magnetic fields after varying the thickness of the magnetic body 11. In these experiments, the current density of the alternating current flowing through the magnetic body 11 was set to j=5×10⁵ Acm⁻², and the magnetic flux density of the external magnetic field was set to _{μ0}H=1 (T). The element structure of the magnetic sensor 10 was SiOₓ (thickness: 15 nm)/Fe—Sn/Al₂O₃ (thickness: 0.33 mm). In these experiments, the ratio of amplitude R^{UMR} of the measured resistance value due to the unidirectional magnetoresistance (UMR) effect to element resistance R₀ (R^{UMR}/R₀) was found.

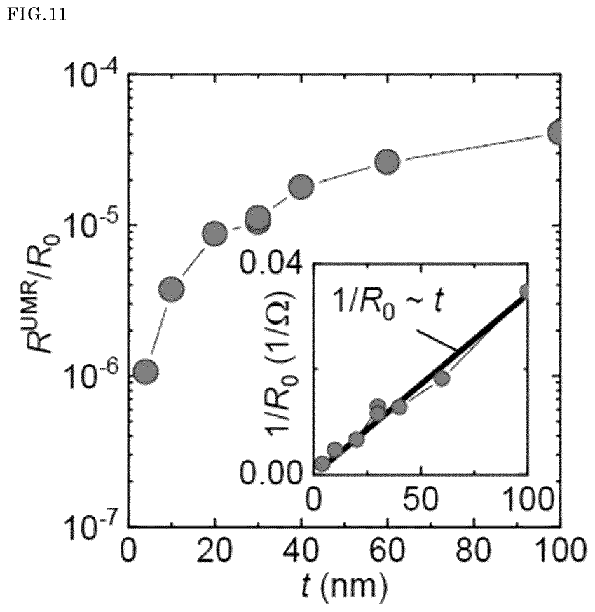

The relationship between the thickness t of the magnetic body 11 and R^{UMR}/R₀ is shown in FIG. 11. The relationship between the thickness t of the magnetic body 11 and 1/R₀ is shown in the inset of FIG. 11. As shown in FIG. 11, it was confirmed that a thicker magnetic body 11 increases the value of R^{UMR}/R₀ and relatively increases the unidirectional magnetoresistance effect. However, as shown in the inset of FIG. 11, a thicker magnetic body 11 results in a smaller element resistance R₀, meaning that the increase in the value of R^{UMR}/R₀ with the thickness of magnetic body 11 cannot be attributed solely to the increase in the unidirectional magnetoresistance effect. This suggests that, in order to improve the accuracy of magnetic field measurement, it is necessary to consider not only the film thickness of the magnetic body 11 but also other effects and element resistance.

The magnetic sensor 10 is not limited to the above description and can be modified as needed. For example, both the resistance value (R₁^{ω}) and the resistance value (R₂^{ω}) due to the AMR effect may be used to determine the output from a predetermined calculation formula.

Additionally, while the magnetic sensor 10 finds the resistance value (R₁^{ω}) and the resistance value (R₂^{ω}) due to the AMR effect, in a case where high angular accuracy is not required and there is a strong demand for miniaturization, for example, measurement may be performed at only one of these two locations. In the variant of the magnetic sensor 10, the resistance value (R₁^{2ω}) and the resistance value (R₂^{2ω}) due to the UMR effect are found, but in a case where high angular accuracy is not required and there is a strong demand for miniaturization, for example, measurement may be performed at either one of these locations.

The magnetic sensor 10 may also have a function that compensates for the effects of ambient temperature or a magnetic field acting as noise in the surrounding area, depending on the actual environment of the applicable equipment, for example, an airplane or passenger car.

### Reference Signs List

10: Magnetic sensor
11: Magnetic body
12: Substrate
13: Cap layer
14: Current application means
15: Detection unit
   15a: Voltage measurement means
   15b: Resistance measurement means
21: First section
22: Second section

1-17. (canceled)

18. A magnetic sensor comprising:
a magnetic body;
a current application means configured to apply an alternating current with a frequency ω to the magnetic body;
a detection unit configured to measure, when the alternating current is applied by the current application means, a change in voltage at the frequency ω in a direction perpendicular to a direction in which the alternating current flows and a change in voltage at a frequency 2ω in a direction parallel to the direction in which the alternating current flows; and
an analysis means configured to detect a three-dimensional magnetic field based on each change in voltage measured by the detection unit.

19. The magnetic sensor according to claim 18, wherein the detection unit also measures, when the alternating current is applied by the current application means, a change in voltage at the frequency ω in the direction parallel to the direction in which the alternating current flows.

20. The magnetic sensor according to claim 18, wherein
the detection unit is configured to measure a resistance value due to an anomalous Hall effect in the magnetic body and a resistance value due to a unidirectional magnetoresistance effect in the magnetic body; and
the analysis means configured to detect a three-dimensional magnetic field based on the resistance values measured by the detection unit.

21. The magnetic sensor according to claim 20, wherein the detection unit is also configured to measure a resistance value due to an anisotropic magnetoresistance effect in the magnetic body.

22. The magnetic sensor according to claim 21, wherein
the detection unit finds the resistance value due to the anomalous Hall effect from the change in voltage at the frequency ω in a direction perpendicular to a direction in which the alternating current flows, finds the resistance value due to the anisotropic magnetoresistance effect from the change in voltage at the frequency ω in a direction parallel to the direction in which the alternating current flows, and finds the resistance value due to the unidirectional magnetoresistance effect from the change in voltage at a frequency 2ω in the direction parallel to the direction in which the alternating current flows.

23. The magnetic sensor according to claim 22, wherein
the magnetic body includes a first section in which the alternating current flows in a predetermined direction when the alternating current is applied by the current application means, and a second section connected to the first section such that the alternating current flows at an angle other than 90 degrees, 180 degrees, 270 degrees and 360 degrees relative to the predetermined direction, and
the detection unit uses, as the change in voltage at the frequency ω in the direction parallel to the direction in which the alternating current flows, a change in voltage at the frequency ω in the direction parallel to the direction in which the alternating current flows in the first section and a change in voltage at the frequency ω in the direction parallel to the direction in which the alternating current flows in the second section.

24. The magnetic sensor according to claim 20, wherein the analysis means determines a zenith angle of the three-dimensional magnetic field based on the resistance value due to the anomalous Hall effect.

25. The magnetic sensor according to claim 20, wherein the analysis means determines an azimuth angle of the three-dimensional magnetic field based on the resistance value due to the unidirectional magnetoresistance effect or a polarity of the resistance value due to the unidirectional magnetoresistance effect.

26. The magnetic sensor according to claim 18, wherein the magnetic body is a material that produces an anomalous Hall effect, an anisotropic magnetoresistance effect, and a unidirectional magnetoresistance effect.

27. The magnetic sensor according to claim 18, wherein the magnetic body is a ferromagnetic body comprising any of Fe—Sn, Co₂MnGa, Co₂MnAl, Fe₃Sn₂, Fe₃Sn, Co₃Sn₂S₂, (Bi,Sb)₂Te₃ doped with Cr or V, and GaMnAs.

28. The magnetic sensor according to claim 18, further comprising:
a substrate supporting the magnetic body; and
a cap layer for preventing deterioration of the magnetic body, wherein
the magnetic body is made of a thin film and is disposed sandwiched between the substrate and the cap layer.

29. The magnetic sensor according to claim 28, wherein the substrate is made of any of Al₂O₃, MgO, and MgAl₂O₄.

30. A device using the magnetic sensor according to claim 18.

31. A magnetic detection method comprising:
applying an alternating current with a frequency ω to a magnetic body; and
detecting a three-dimensional magnetic field based on a change in voltage at the frequency ω in a direction perpendicular to a direction in which the alternating current flows and a change in voltage at a frequency 2ω in a direction parallel to the direction in which the alternating current flows.

32. The magnetic detection method according to claim 31, further comprising detecting the three-dimensional magnetic field by also using a change in voltage at the frequency ω in a direction parallel to the direction in which the alternating current flows.

33. The magnetic detection method according to claim 31, wherein
detecting a three-dimensional magnetic field based on a resistance value due to an anomalous Hall effect in the magnetic body and a resistance value due to a unidirectional magnetoresistance effect in the magnetic body.

34. The magnetic detection method according to claim 33, further comprising detecting the three-dimensional magnetic field by also using a resistance value due to an anisotropic magnetoresistance effect in the magnetic body.
